(19) United States
(12) Patent Application Publication
(10) Pub. No.: US 2022/0295668 A1
(43) Pub. Date: Sep. 15, 2022

(54) DATA STORAGE DEVICE COOLING

(71) Applicant: Seagate Technology LLC, Fremont, CA (US)

(72) Inventor: Akhil Namboori, Singapore (SG)

(21) Appl. No.: 17/200,347

(22) Filed: Mar. 12, 2021

(51) Int. Cl. H05K 7/20; G11B 33/14

(52) U.S. Cl. CPC H05K 7/20336; G11B 33/1413

(57) ABSTRACT

A data storage device including a passive cooling system. The data storage device including an enclosure and a printed circuit board coupled to the enclosure. The data storage device also including a vapor chamber coupled to the printed circuit board and one or more heat pipes in fluid communication with the vapor chamber. The vapor chamber and one or more heat pipes including a two-phase liquid therein and defining a thickness of less than or equal to 0.7 mm. The two-phase liquid dissipating heat within the data storage device by evaporating and condensing. In some embodiments, the data storage device also including a disk separator positioned between adjacent recording disks and acting similar to the vapor chamber.

The disclosure herein relates to passively cooling data storage devices and systems of the same.

### SUMMARY

An illustrative apparatus may include a data storage device enclosure and a printed circuit board operably coupled to the data storage device enclosure. The apparatus may also include a vapor chamber coupled to the printed circuit board and one or more heat pipes extending from the vapor chamber. The vapor chamber may define an inner vapor cavity having a two-phase liquid contained therein. The one or more heat pipes may define an inner pipe cavity in fluid communication with the inner vapor cavity such that the two-phase liquid can move between the inner vapor cavity and the inner pipe cavity. Each of the vapor chamber and the one or more heat pipes may define a thickness of less than or equal to 0.7 millimeters.

An illustrative system may include a data storage device enclosure including a printed circuit board coupled to an outer surface of the data storage device enclosure. The system may also include a casing surrounding at least a portion of the data storage device enclosure. Further, the system may include a vapor chamber coupled to the printed circuit board and positioned between the data storage device enclosure and the casing. The vapor chamber may define an inner vapor cavity having a two-phase liquid contained therein. The system may also include one or more heat pipes extending from the vapor chamber and positioned between the data storage device enclosure and the casing. The one or more heat pipes may define an inner pipe cavity in fluid communication with the inner vapor cavity such that the two-phase liquid can move between the inner vapor cavity and the inner pipe cavity.

An illustrative data storage device enclosure may include a drive base, a spindle attached to the drive base, a plurality of recording disks rotatably coupled to the spindle, and a head stack assembly including at least one head for reading and writing data from and to a recording disk of the plurality of recording disks. The data storage device enclosure may also include a disk separator positioned between a pair of adjacent recording disks of the plurality of recording disks. The disk separator may define an inner cavity having a two-phase liquid contained therein.

The above summary is not intended to describe each embodiment or every implementation of the present disclosure. A more complete understanding will become apparent and appreciated by referring to the following detailed description and claims taken in conjunction with the accompanying drawings. In other words, these and various other features and advantages will be apparent from a reading of the following detailed description.

### BRIEF DESCRIPTION OF THE DRAWINGS

The disclosure may be more completely understood in consideration of the following detailed description of various embodiments of the disclosure in connection with the accompanying drawings.

FIG. 1A illustrates a data storage device including a passive cooling system in accordance with embodiments of the present disclosure.

FIG. 1B illustrates an exploded view of the device and system of FIG. 1A.

FIG. 2 illustrates a top view of the passive cooling system positioned on a printed circuit board of FIG. 1A.

FIG. 3A illustrates a casing surrounding the data storage device of FIG. 1A.

FIG. 3B illustrates a cross-sectional view of FIG. 3A.

FIG. 4 illustrates an another embodiment of device and casing of FIG. 3B.

FIG. 5A illustrates a data storage device including another passive cooling system in accordance with embodiments of the present disclosure.

FIG. 5B illustrates an isolated and exploded view of the passive cooling system of FIG. 5A.

### DETAILED DESCRIPTION

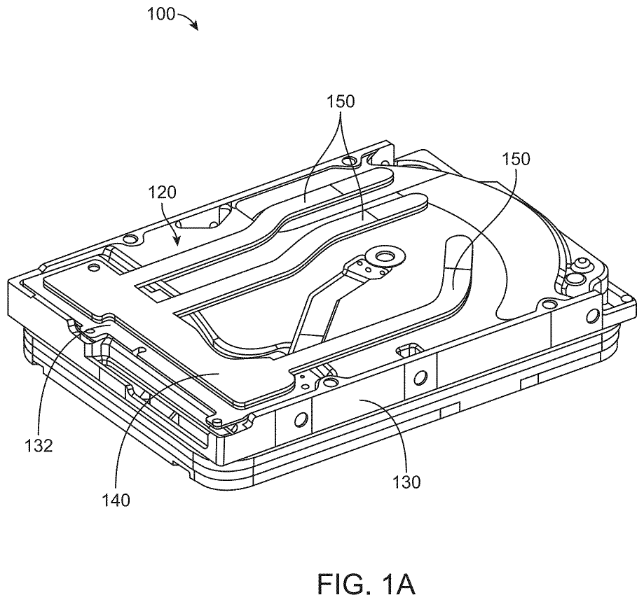

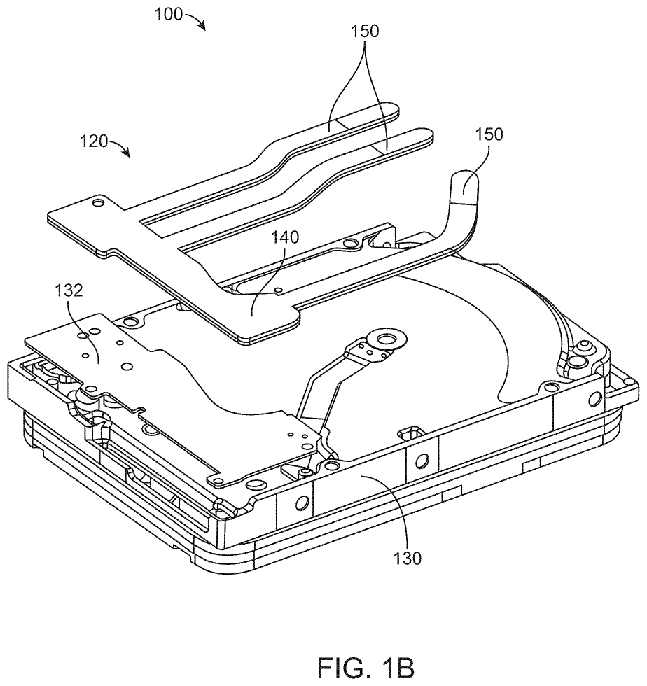

Exemplary systems, apparatus, and methods shall be described with reference to FIGS. 1-5. It will be apparent to one skilled in the art that elements or processes from one embodiment may be used in combination with elements or processes of the other embodiments, and that the possible embodiments of such systems, apparatus, and methods using combinations of features set forth herein is not limited to the specific embodiments shown in the figures and/or described herein. Further, it will be recognized that the size and shape of various elements herein may be modified but still fall within the scope of the present disclosure, although certain one or more shapes and/or sizes, or types of elements, may be advantageous over others.

The present disclosure relates to passively cooling data storage devices. The design of data storage devices continue to have faster rotational speeds and seek times, as the industry pushes the limits of recording densities. This results in more power consumption and, in turn, generates more heat. One of the key issues with high density storage devices is thermal dissipation, which may make the device prone to higher failure rates (e.g., due to increased heat).

Current widespread solutions to increased heat generation include actively controlled fan cooled systems. However, actively controlled fan cooled systems may have some issues because of the increased cost to set up complex air circulation systems, the noise levels associated with multiple fans running concurrently, and power and space necessary for the multiple fans.

Therefore, it may be desirable to include passive cooling mechanisms for thermal management of data storage devices at a drive level to significantly reduce power and running cost (e.g., by using fewer fans or fans at a lower speed). Further, a passive cooling mechanism could eliminate the need for active cooling systems in the drive.

Specifically, the passive cooling system for the data storage devices may include a combination of a vapor chamber (or multiple vapor chambers) and one or more heat pipes. The vapor chamber and one or more heat pipes may utilize air and a two-phase liquid/working fluid in an inner cavity of each to transfer and dissipate heat. For example, the vapor chamber may act as a heat spreader and may uniformly spread the heat from hotspots of the data storage device (e.g., at a printed circuit board of the device). The one or more heat pipes may act as a heat dissipator to remove the heat from the vapor chamber to cooler parts of the system. In particular, the two-phase liquid may evaporate due to heat within the vapor chamber (e.g., thereby extracting heat therefrom) and travel to cooler regions within the vapor chamber or through the one or more heat pipes. After the evaporated two-phase liquid reaches a cooler region, the two-phase liquid may condense and travel back to the vapor chamber. In other words, the vapor chamber may act as an evaporator and the one or more heat pipes may act as a condenser to dissipate heat into the ambient surroundings.

Additionally, in one or more embodiments, the disk separators of the data storage device may also act as a vapor chamber. For example, the disk separators may be used to help separate the recording disks, while also assisting with thermal management within the device. In other words, the disk separator may be provided with an auxiliary purpose of heat dissipation without disrupting the internal configuration of the device (e.g., because the external profile and characteristics of the disk separator would not be altered).

Reference will now be made to the drawings, which depict one or more aspects described in this disclosure. However, it will be understood that other aspects not depicted in the drawings fall within the scope and spirit of this disclosure. Like numbers used in the figures refer to like components, elements, portions, regions, openings, apertures, and the like. However, it will be understood that the use of a reference character to refer to an element in a given figure is not intended to limit the element in another figure labeled with the same reference character.

FIGS. 1A and 1B illustrate a data storage device 100 (e.g., a magnetic disk or hard disk drive) including a passive cooling system 120. The data storage device 100 may include any suitable type of data storage device. For example, the data storage device 100 may define any form factor, capacity size, and/or interface connection. The data storage device 100 may include a data storage device enclosure 130 (e.g., a housing) and a printed circuit board 132 operably coupled to the data storage device enclosure 130 (e.g., to an outer surface of the data storage device enclosure). The data storage device enclosure 130 may physically protect the internal components of the data storage device 100 and the printed circuit board 132 may assist in controlling the data storage device 100.

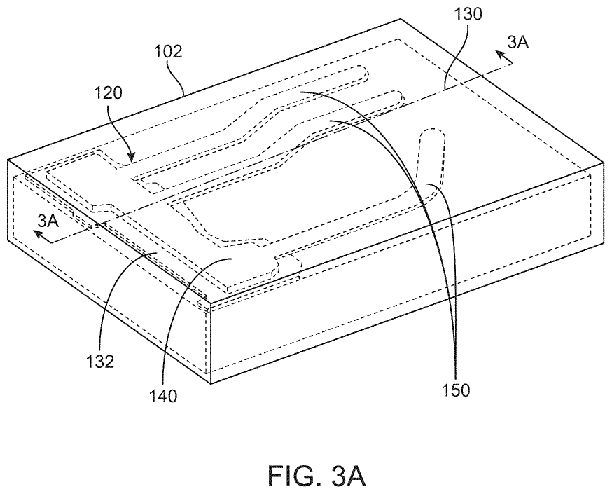

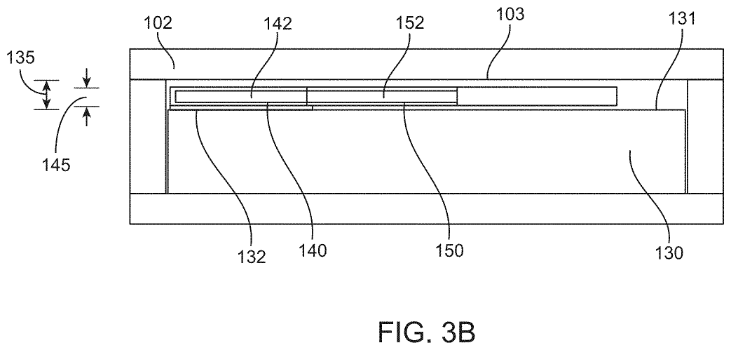

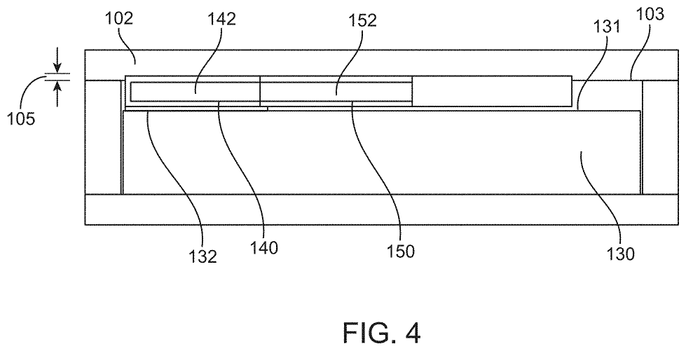

The data storage device 100 may further include a vapor chamber 140 coupled to the printed circuit board 132 to, e.g., dissipate heat created by the printed circuit board 132. In one or more embodiments, the vapor chamber 140 may directly contact the printed circuit board 132. For example, the printed circuit board 132 may define a flat surface upon which the vapor chamber 140 contacts. In other embodiments, the vapor chamber 140 may be connected indirectly to the printed circuit board 132 (e.g., due to adhesive or a gap or connected through another component). The vapor chamber 140 may define an inner vapor cavity 142 (e.g., as shown in FIGS. 3B and 4) having a two-phase liquid contained therein. For example, the two-phase liquid may include water, acetone, methanol, propylene, etc.

The two-phase liquid may cycle between liquid and vapor to assist in dissipating heat within the vapor chamber 140. For example, the two-phase liquid contained within the inner vapor cavity 142 may evaporate due to heat or hot spots on the data storage device 100 (e.g., from the printed circuit board 132) that are in contact with the vapor chamber 140. The evaporated two-phase liquid may then move to cooler sections of the inner vapor cavity 142 (or, e.g., into an inner pipe cavity 152 of one or more heat pipes 150 as will be described further herein). After the evaporated two-phase liquid moves to a cool section of the cooling system 120, the two-phase liquid may condense and move back to hotter sections of the cooling system 120.

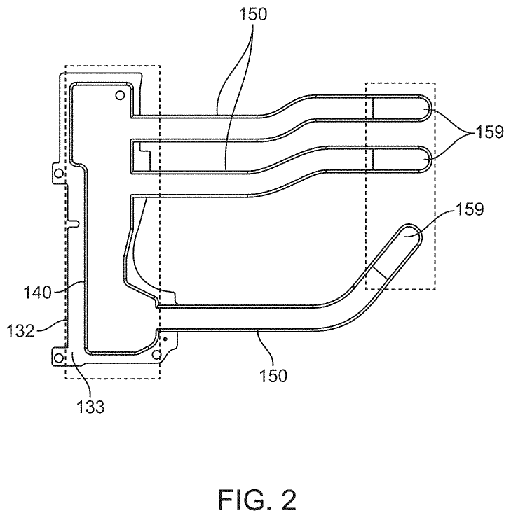

The vapor chamber 140 may define any suitable shape and size. For example, the vapor chamber 140 may define a size along a plane parallel to the surface of the data storage device 100 of about 93 millimeters by about 35 millimeters. In one embodiment, the vapor chamber 140 may cover greater than or equal to about 50%, greater than or equal to about 75%, greater than or equal to about 80%, greater than or equal to about 85%, greater than or equal to about 90%, greater than or equal to 95% of a surface area 133 (e.g., shown in FIG. 2) of the printed circuit board 132 (e.g., of a surface 133 opposite the surface attached to the data storage device enclosure 130). In one or more embodiments, the vapor chamber 140 may only be located at the printed circuit board 132. In one or more embodiments, the vapor chamber 140 may match or follow the contours of the printed circuit board 132 (e.g., inside of, outside of, or exactly along the edge of the boundary of the printed circuit board 132). In other embodiments, the vapor chamber 140 may extend beyond the boundaries of the printed circuit board 132 (e.g., to other portions of the data storage device enclosure 130).

Further, the vapor chamber 140 may define any suitable thickness. For example, the vapor chamber 140 may be positioned in a gap between the data storage device enclosure 130 and an outer casing 102 (as will be disclosed further herein). In other words, the thickness of the vapor chamber 140 may be restricted or controlled by physical limitations of the data storage device 100. Specifically, in one or more embodiments, the vapor chamber 140 may define a thickness of less than or equal to about 2 millimeters, less than or equal to about 1.5 millimeters, less than or equal to about 1 millimeter, less than or equal to about 0.7 millimeters, less than or equal to about 0.3 millimeters, etc.

The vapor chamber 140 may include (e.g., be formed of) any suitable materials. For example, the vapor chamber 140 may include copper, aluminum, stainless steel, titanium, etc. The vapor chamber 140 may be constructed in any suitable way. For example, the vapor chamber 140 may include a wide and oblong tube or may include two plates stamped together along the edges. Further, in one or more embodiments, the inner surface of the inner vapor cavity 142 may include a wicking material through which the condensed two-phase liquid may travel from cooler locations of the vapor chamber 140 to the warmer locations of the vapor chamber 140.

The data storage device 100 may also include one or more heat pipes 150 extending from the vapor chamber 140. Each heat pipe of the one or more heat pipes 150 may define an inner pipe cavity 152 (e.g., as shown in FIGS. 3B and 4) that is similar to the inner vapor cavity 142 of the vapor chamber 140. Further, the inner pipe cavity 152 may be in fluid communication with the inner vapor cavity 142 such that the two-phase liquid (e.g., in evaporated or condensed form) can move between the inner vapor cavity 142 and the inner pipe cavity 152. For example, the evaporated two-phase liquid may move from the vapor chamber 140 to the one or more heat pipes 150. Also, for example, the condensed two-phase liquid may move from the one or more heat pipes 150 to the vapor chamber 140. Specifically, the two-phase liquid may evaporate when located at a portion of one or both of the vapor chamber 140 and the one or more pipes 150 that has a higher temperature, and move towards and condense when located at a portion of one or both of the vapor chamber 140 and the one or more pipes 150 that has a lower temperature. In at least one simulation analysis, the components on the printed circuit board 132 (which can reach up to 100° C.) may be reduced by about 50% with the present passive cooling system 120 in a 25° C. environment.

The one or more heat pipes 150 may include any suitable number of heat pipes. For example, as shown in FIGS. 1 and 2, the data storage device includes three heat pipes. The one or more heat pipes 150 may be arranged in any suitable way to efficiently and effectively dissipate heat from the data storage device 100. For example, the one or more heat pipes 150 may be arranged in any contour along the shape of the base deck of the drive (e.g., to assist in transferring the heat from the vapor chamber 140 to walls of the drive). Each heat pipe of the one or more heat pipes 150 may extend from being attached to the vapor chamber 140 to a free end 159 of the heat pipe 150 in such a way to transport the two-phase liquid to a cooler section of the data storage device 100. In other words, the free end 159 of the heat pipe 150 may be located at a cooler section of the data storage device 100. Specifically, the free end 159 of the heat pipe 150 may be positioned at or over the base deck opposite the printed circuit board 132 (e.g., which is cooler than the printed circuit board 132. In essence, the vapor chamber 140 may act as an evaporator, while the free end 159 of the one or more heat pipes 150 may act as a condenser.

Further, multiple heat pipes of the one or more heat pipes 150 may be positioned relative to one another to maximize the cooling effect of the one or more heat pipes 150 (e.g., in combination with the vapor chamber 140). For example, the heat pipes 150 may separately extend from the vapor chamber 140 and be space apart from one another by greater than or equal to about 5 mm, greater than or equal to about 10 mm, etc. and/or less than or equal to about 20 mm, less than or equal to about 15 mm, etc. at the point from which each extends from the vapor chamber 140. Further, in one or more embodiments, any portion of each of the heat pipes 150 may be spaced apart from one another by greater than or equal to about 20 mm, greater than or equal to about 25 mm, greater than or equal to about 30 mm, etc. and/or less than or equal to about 50 mm, less than or equal to about 40 mm, less than or equal to about 35 mm, etc. The space between each of the one or more heat pipes 150 may provide additional room for heat from the one or heat pipes to dissipate into the ambient surrounding air. Although, in some embodiments, two heat pipes of the one or more heat pipes 150 may be directly adjacent or in contact with one another.

Specifically, in one or more embodiments, the one or more heat pipes 150 may include a first heat pipe and a second heat pipe. In one or more embodiments, the first and second heat pipes may extend parallel to one another. In one or more embodiments, at least a portion of the second heat pipe may extend at an angle to the first heat pipe. Further, the heat pipe may extend perpendicular to or at an angle to an edge of the vapor chamber 140. Specifically, as shown in FIG. 2, a first heat pipe 154 may extend from the vapor chamber 140 along a similar path (but spaced apart therefrom) as a second heat pipe 156. Further, a third heat pipe 158 may extend from the vapor chamber 140 in a different arrangement than either of the first and second heat pipes 154, 156.

The one or more heat pipes 150 may be any suitable shape and size. For example, the one or more heat pipes 150 may define a width of greater than or equal to about 4 millimeters, greater than or equal to about 6 millimeters, greater than or equal to about 8 millimeters, etc. and/or less than or equal to about 15 millimeters, less than or equal to about 12 millimeters, less than or equal to about 10 millimeters, etc. Further, the one or more heat pipes 150 and the vapor chamber 140 may cover at least 50%, 60%, 70%, or 80% of a surface area (e.g., a surface upon which the printed circuit board 132 is coupled) of the data storage device enclosure 131.

The one or more heat pipes 150 may define any suitable thickness. For example, the one or more heat pipes 150 may be positioned in a gap between the data storage device enclosure 130 and an outer casing 102. In other words, the thickness of the one or more heat pipes may be restricted or controlled by physical limitations of the data storage device 100. Specifically, the one or more heat pipes 150 may define a thickness of less than or equal to about 2 millimeters, less than or equal to about 1.5 millimeters, less than or equal to about 1 millimeter, less than or equal to about 0.7 millimeters, less than or equal to about 0.3 millimeters, etc. Further, the thickness of the vapor chamber 140 and the one or more heat pipes 150 may be the same or different. Further yet, in one or more embodiments, each of the vapor chamber 140 and the one or more heat pipes 150 may define varying thickness. Additionally, the vapor chamber 140 and the one or more heat pipes 150 may be positioned such that there is a gap between casing 102 and one or both of the vapor chamber 140 and the one or more heat pipes 150. For example, the gap between the vapor chamber 140 (and/or the one or more heat pipes 150) and the casing 102 may be less than or equal to 0.5 millimeters, less than or equal to 0.4 millimeters, less than or equal to 0.3 millimeters, less than or equal to 0.2 millimeters, less than or equal to 0.1 millimeters.

The one or more heat pipes 150 may include (e.g., be formed of) any suitable materials. For example, the one or more heat pipes 150 may include copper, aluminum, titanium, stainless steel, etc. The one or more pipes 150 may be constructed in any suitable way. For example, in one or more embodiments, the inner surface of the inner pipe cavity 152 may include a wicking material through which the condensed two-phase liquid may travel from cooler locations of the one or more heat pipes 150 to the warmer locations of the one or more heat pipes 150.

In one or more embodiments (e.g., as shown in FIG. 3A), the data storage device 100 may include a casing 102 surrounding at least a portion of the data storage device enclosure 130 (e.g., the data storage device enclosure 130 and passive cooling system 100 are shown in broken lines in FIG. 3A). For example, in one or more embodiments, the casing may include a heat sink design having fins for increased thermal dissipation. Further, the casing 102 may include (e.g., be formed of) any suitable material. For example, the casing 102 may include aluminum. In one or more embodiments, the vapor chamber 140 may be positioned between the data storage device enclosure 130 (or, e.g., the printed circuit board 132) and at least a portion of the casing 102. Also, in one or more embodiments, the one or more heat pipes 150 may be positioned between the data storage device enclosure 130 and at least a portion of the casing 102. The vapor chamber 140 and the one or more heat pipes 150 may be included in the data storage device 100 without making any design (e.g., structural/spacing) changes to the data storage device enclosure 130 or outer casing 102.

Therefore, as described herein, the thickness of one or both of the vapor chamber 140 and the one or more heat pipes 150 may be restricted by the space limitations between the casing 102 and the data storage device enclosure 130. In other words, the gap size between the casing 102 and the data storage device enclosure 130 may control the maximum thickness of the vapor chamber 140 and/or the one or more heat pipes 150. For example, as shown in FIG. 3B (which is a cross-sectional view of FIG. 3A taken along 3A-3A), the vapor chamber 140 and one or more heat pipes 150 are positioned between a surface 131 of the data storage device enclosure 130 and an inner surface 103 of the casing 102. Further, the thickness 145 of the vapor chamber 140 and the one or more heat pipes 150 is a less than the gap 135 between the surface 131 of the data storage device enclosure 130 and the inner surface 103 of the casing 102. As such, the vapor chamber 140 and/or the one or more heat pipes 150 may be positioned a gap distance from the data storage device enclosure 130 of less than or equal to 0.5 millimeters, less than or equal to 0.4 millimeters, less than or equal to 0.3 millimeters, less than or equal to 0.2 millimeters, less than or equal to 0.1 millimeters.

However, in some embodiments, one or both of the vapor chamber 140 and the one or more heat pipes 150 may be embedded in the casing 102 (e.g., as shown in FIG. 4, an alternative cross-sectional view of FIG. 3A taken along 3A-3A). For example, in one or more embodiments, the casing 102 may define one or more grooves (e.g., channels) within the inner surface 103 of the casing 102 facing the data storage device enclosure 130. The one or more grooves may extend into the inner surface 103 to define a depth 105 by greater than or equal to 0.5 mm, greater than or equal to 0.8 mm and/or less than or equal to 1.5 mm, less than or equal to 1 mm (e.g., depending on the thickness of the heat pipe and/or the vapor chamber). One or both of the vapor chamber 140 and the one or more heat pipes 150 may be positioned (at least partially) in the one or more grooves of the casing 102. As such, heat from the vapor chamber 140 and/or the one or more heat pipes 150 may also be transferred through the outer casing 102 to help reduce the internal temperature of the data storage device 100. In one or more embodiments, only a portion of one or both of the vapor chamber 140 and the one or more heat pipes 150 may be positioned within the one or more grooves 104. Although, in other embodiments, the vapor chamber 140 and/or the one or more heat pipes 150 may not extend past the plane of the inner surface 103 of the casing 102 (e.g., as shown in FIG. 3A).

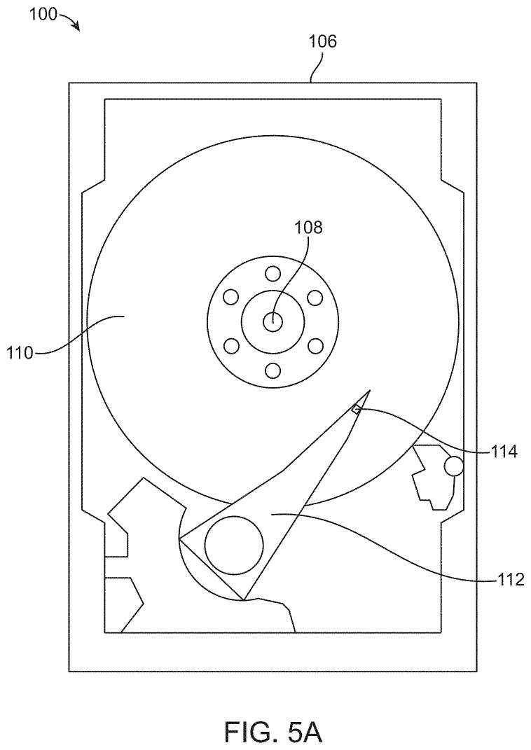

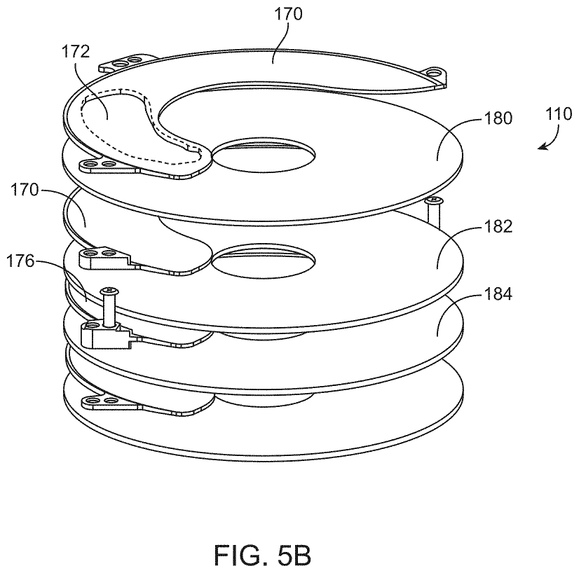

Furthermore, another embodiment of a cooling system is shown in FIG. 5A. For example, the data storage device 100 may include a drive base 106, a spindle 108 attached to the drive base 106, and a plurality of recording disks 110 rotatably coupled to the spindle 108. The data storage device 100 may also include a head stack assembly 112 including at least one head 114 for reading data from and writing data to a recording disk of the plurality of recording disks 110.

The data storage device 100 may also include a disk separator 170 positioned between a pair of adjacent recording disks of the plurality of recording disks 110 as shown in FIG. 5B (e.g., which shows an isolated exploded view of the recording disks and separators of FIG. 5A). In one or more embodiments, the disk separator 170 may define an inner cavity 172 (e.g., within the broken-away section of the top disk separator 170 of FIG. 5B) having a two-phase liquid contained therein. In other words, the disk separator 170 may act similar to the vapor chamber 140 and one or more heat pipes 150 described herein to dissipate heat within the data storage device 100 (e.g., due to air flow and movement of the two-phase liquid). Further, the disk separator 170 defining an inner cavity 172 containing a two-phase liquid may be configured to replace the typical disk separator that separates adjacent recording disks.

The disk separator 170 may include (e.g., be formed of) any suitable material. For example, the disk separator 170 may include copper, aluminum, etc. Further, the disk separator 170 may define any suitable dimensions. For example, the disk separator 170 define a thickness of less than or equal to about 2 millimeters, less than or equal to about 1.5 millimeters, less than or equal to about 1 millimeter, less than or equal to about 0.7 millimeters, less than or equal to about 0.3 millimeters, etc. Specifically, the thickness may be restricted or defined by the distance between adjacent recording disks 110. Furthermore, the disk separator 170 may cover greater than or equal to 20%, greater than or equal to 30%, greater than or equal to 40%, etc. and/or less than or equal to 70%, less than or equal to 60%, less than or equal to 50%, etc. of a surface area of a recording disk of the plurality of recording disks.

Additionally, the data storage device 100 may include any number of suitable disk separators 170 acting as a cooling system. For example, the data storage device 100 may include more than one disk separator, each positioned between a different pair of adjacent recording disks 110. Specifically, the pair of adjacent recording disks may include a first recording disk 180 and a second recording disk 182 (e.g., as shown in FIG. 5B). The plurality of recording disks 110 may further include a third recording disk 184 closer to the second recording disk 182 than the first recording disk 180. The disk separator 170 (e.g., defining an inner cavity with a two-phase liquid) may be positioned between the first and second recording disks 180, 182 and an additional disk separator 176 (e.g., defining an inner cavity with a two-phase liquid) may be positioned between the second and third recording disks 182, 184.

In the preceding description, reference is made to the accompanying set of drawings that form a part hereof and in which are shown by way of illustration several specific embodiments. It is to be understood that other embodiments are contemplated and may be made without departing from (e.g., still falling within) the scope or spirit of the present disclosure. The preceding detailed description, therefore, is not to be taken in a limiting sense. The definitions provided herein are to facilitate understanding of certain terms used frequently herein and are not meant to limit the scope of the present disclosure.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. The recitation of numerical ranges by endpoints includes all numbers subsumed within that range (e.g., 1 to 5 includes 1, 1.5, 2, 2.75, 3, 3.80, 4, and 5) and any range within that range.

As used in this specification and the appended claims, the singular forms “a,” “an,” and “the” encompass embodiments having plural referents, unless the content clearly dictates otherwise. As used in this specification and the appended claims, the term “or” is generally employed in its sense including “and/or” unless the content clearly dictates otherwise. As used herein, “or” is generally employed in its sense including “and/or” unless the content clearly dictates otherwise. As used herein, “have,” “having,” “include,” “including,” “comprise,” “comprising,” or the like are used in their open-ended sense, and generally mean “including, but not limited to.”

Embodiments of the systems, apparatus, and methods associated therewith are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation, and the present disclosure is limited only by the claims that follow.

What is claimed is:

1. An apparatus comprising:
a data storage device enclosure;
a printed circuit board operably coupled to the data storage device enclosure;
a vapor chamber coupled to the printed circuit board, wherein the vapor chamber defines an inner vapor cavity having a two-phase liquid contained therein;
one or more heat pipes extending from the vapor chamber, wherein the one or more heat pipes define an inner pipe cavity in fluid communication with the inner vapor cavity such that the two-phase liquid can move between the inner vapor cavity and the inner pipe cavity, wherein each of the vapor chamber and the one or more heat pipes defines a thickness of less than or equal to 0.7 millimeters.

2. The apparatus of claim 1, wherein the vapor chamber covers at least 90% of a surface area of the printed circuit board.

3. The apparatus of claim 1, wherein each of the vapor chamber and the one or more heat pipes defines a thickness of less than or equal to 0.3 millimeters.

4. The apparatus of claim 1, wherein one or more heat pipes comprises three heat pipes separately extending from the vapor chamber.

5. The apparatus of claim 1, wherein the vapor chamber directly contacts the printed circuit board.

6. The apparatus of claim 1, wherein each of the one or more heat pipes are spaced apart from one another by at least 10 mm.

7. The apparatus of claim 1, wherein the one or more heat pipes comprise a first heat pipe and a second heat pipe extending in direction parallel to the first heat pipe.

8. The apparatus of claim 1, wherein the one or more heat pipes comprise a first heat pipe and a second heat pipe, wherein at least a portion of the second heat pipe extends at an angle to the first heat pipe.

9. The apparatus of claim 1, wherein the one or more heat pipes and the vapor chamber covers at least 70% of a surface area of the data storage device enclosure.

10. A system comprising:
a data storage device enclosure comprising a printed circuit board coupled to an outer surface of the data storage device enclosure;
a casing surrounding at least a portion of the data storage device enclosure;
a vapor chamber coupled to the printed circuit board and positioned between the data storage device enclosure and the casing, wherein the vapor chamber defines an inner vapor cavity having a two-phase liquid contained therein;
one or more heat pipes extending from the vapor chamber and positioned between the data storage device enclosure and the casing, wherein the one or more heat pipes define an inner pipe cavity in fluid communication with the inner vapor cavity such that the two-phase liquid can move between the inner vapor cavity and the inner pipe cavity.

11. The system of claim 10, wherein the one or more heat pipes are embedded in the casing.

12. The system of claim 10, wherein the casing defines one or more grooves within a surface of the casing facing the data storage device enclosure, wherein the one or more heat pipes are positioned in the one or more grooves of the casing.

13. The system of claim 10, wherein each of the vapor chamber and the one or more heat pipes defines a thickness of less than or equal to 0.7 millimeters.

14. The system of claim 10, wherein the vapor chamber covers at least 90% of a surface area of the printed circuit board.

15. The system of claim 10, wherein the vapor chamber directly contacts the printed circuit board.

16. A data storage device enclosure comprising:
a drive base;
a spindle attached to the drive base;
a plurality of recording disks rotatably coupled to the spindle;
a head stack assembly comprising at least one head for reading and writing data from and to a recording disk of the plurality of recording disks; and
a disk separator positioned between a pair of adjacent recording disks of the plurality of recording disks, wherein the disk separator defines an inner cavity having a two-phase liquid contained therein.

17. The data storage device enclosure of claim 16, wherein the disk separator defines a thickness of 0.8 mm to 1 mm.

18. The data storage device enclosure of claim 16, wherein the disk separator covers 20% to 50% of a surface area of a recording disk of the plurality of recording disks.

19. The data storage device enclosure of claim 16, wherein the pair of adjacent recording disks comprises a first recording disk and a second recording disk, wherein the plurality of recording disks further comprises a third recording disk closer to the second recording disk than the first recording disk, wherein the disk separator is positioned between the first and second recording disks and an additional disk separator is positioned between the second and third recording disks.

20. The data storage device enclosure of claim 16, wherein the disk separator comprises copper.
